(19) United States
(12) Patent Application Publication
(10) Pub. No.: US 2026/0095039 A1
(43) Pub. Date: Apr. 2, 2026

(54) DUAL-DETECTION LEAKAGE PROTECTOR

(71) Applicant: DONGGUAN TUOCHENG INDUSTRIAL CO., LTD., Dongguan (CN)

(72) Inventor: Juntuo YANG, Dongguan (CN)

(73) Assignee: DONGGUAN TUOCHENG INDUSTRIAL CO., LTD., Dongguan (CN)

(21) Appl. No.: 19/324,187

(22) Filed: Sep. 10, 2025

Related U.S. Application Data
(63) Continuation of application No. PCT/CN2024/122945, filed on Sep. 30, 2024.

(51) Int. Cl. H02H 3/32; G01R 31/52; H02H 3/04; H02H 5/04

(52) U.S. Cl. CPC H02H 3/32; G01R 31/52; H02H 3/04; H02H 5/047

(57) ABSTRACT

A dual-detection leakage protector is provided. The dual-detection leakage protector includes a switching unit, a rectifier module unit, a temperature control detection unit, a leakage detection unit, and a triggering unit, where the switching unit is disposed between an input terminal and an output terminal; the temperature control detection unit includes one terminal connected to an output terminal of the rectifier module unit, and the other terminal connected to the triggering unit; the leakage detection unit is disposed around a power cord connected between the switching unit and the input terminal; and the triggering unit is configured to acquire information of the temperature control detection unit or the leakage detection unit and control on-off of the switching unit, thereby cutting off the circuit. The dual-detection leakage protector has the temperature control detection function and the leakage detection function.

### CROSS-REFERENCE TO THE RELATED APPLICATIONS

This application is a continuation application of International Application No. PCT/CN2024/122945, filed on Sep. 30, 2024, the entire contents of which are incorporated herein by reference.

### TECHNICAL FIELD

The present disclosure belongs to the field of electrical technologies, and particularly relates to a dual-detection leakage protector.

### BACKGROUND

Leakage protectors are power cord devices with a plug, and are used to detect a leakage current between a live or neutral wire and a protective shield of a power cord from the power plug to the loaded electrical appliance (such as the air-conditioner and the dehumidifier). In the case of a leakage current, the leakage protector cuts off the power supply of the electrical appliance to prevent the fire and ensure the safety. It is designed to prevent damage and insulation degradation of the power cord caused by aging, wear, squeezing or animal bites, thereby avoiding arc fault-induced fires. However, the leakage protector (the plug) and the socket become loose easily after used for a period of time, resulting in poor contact. This causes high-temperature flash fires in conduction, potentially burning the plug and the socket or even triggering the fire.

Therefore, a leakage protector integrated with a temperature control detection function and a leakage detection function is desired to solve the defects of the existing product.

### SUMMARY

In view of defects and shortages of the prior art, the present disclosure provides a dual-detection leakage protector integrated with temperature control detection and leakage detection.

To achieve the above objective, the technical solutions of the present disclosure are as follows: The present disclosure provides a dual-detection leakage protector, including a switching unit, a rectifier module unit, a temperature control detection unit, a leakage detection unit, and a triggering unit, where
the switching unit is disposed between an input terminal and an output terminal, and configured to switch the input terminal and the output terminal on or off; the input terminal includes a live wire input terminal and a neutral wire input terminal; and the output terminal includes a neutral wire output terminal electrically connected to the neutral wire input terminal and a live wire output terminal electrically connected to the live wire input terminal;
the rectifier module unit is connected between the input terminal and the output terminal, and configured to provide direct current (DC) power for a circuit;
the temperature control detection unit includes one terminal connected to an output terminal of the rectifier module unit, and the other terminal connected to the triggering unit, and is configured to detect a temperature of a power cord plug-in connector;
the leakage detection unit is disposed around a power cord connected between the switching unit and the input terminal, and configured to detect whether the power cord has a leakage current; and
the triggering unit is configured to acquire information of the temperature control detection unit or the leakage detection unit and control on-off of the switching unit, thereby cutting off the circuit.

As a further solution to the present disclosure, the temperature control detection unit is a temperature control component; and the temperature control component includes one terminal connected to the output terminal of the rectifier module unit, and the other terminal connected to the triggering unit.

As a further solution to the present disclosure, the temperature control detection unit includes a temperature control switch, a resistor R29, a thyristor SCR1, a diode D11, a diode D12, and a diode D13; the temperature control switch includes one terminal grounded, and the other terminal connected to the live wire input terminal through the resistor R29; and the thyristor SCR1 includes a control terminal connected between the temperature control switch and the resistor R29, a cathode grounded, and an anode connecting the diode D11, the diode D12 and the diode D13 in series to the triggering unit.

As a further solution to the present disclosure, the temperature control detection unit includes a temperature control switch, a resistor R29, a control chip IC1, a triode Q5, a thyristor SCR2, a resistor R30, and a warning lamp LED4; the temperature control switch includes one terminal grounded, and the other terminal connected to the live wire input terminal through the resistor R29; a base of the triode Q5 is connected between the temperature control switch and the resistor R29, and connected to an input terminal of the control chip IC1; and the thyristor SCR2 includes a control terminal connected to an output terminal of the control chip IC1, a cathode grounded, and an anode connecting the warning lamp LED4 and the resistor R30 in series to the output terminal of the rectifier module unit.

As a further solution to the present disclosure, the triggering unit includes a triode Q2, a triode Q1, a resistor R32, a resistor R20, a trip coil SOL, a metal oxide semiconductor (MOS) transistor Q3, an MOS transistor Q4, a resistor R18, a resistor R19, a voltage stabilizing resistor ZD3, a diode D6, a resistor R16, a diode D5, a resistor R17, a resistor R21, a diode D10, a diode D9, a resistor R26, a capacitor C11, and a thyristor SCR; a terminal of the resistor R18 connected in series with the resistor R19 is connected to the output terminal of the rectifier module unit, and the other terminal of the resistor R18 is grounded; a terminal of the resistor R16 connected in series with the reversely disposed diode D5 and the resistor R17 is connected to the output terminal of the rectifier module unit, and the other terminal of the resistor R16 is grounded; the voltage stabilizing resistor ZD3 is connected in series with the diode D6, and includes one terminal connected between the resistor R18 and the resistor R19, and the other terminal connected between the reversely disposed diode D5 and the resistor R17; a first switching terminal of the MOS transistor Q3 is connected between the resistor R16 and the reversely disposed diode D5 through the resistor R21; the diode D9 is connected in series with the resistor R26 and the capacitor C11, and includes one terminal connected to the live wire input terminal, and the other terminal grounded; both a control terminal of the MOS transistor Q3 and a first switching terminal of the MOS transistor Q4 are connected between the resistor R26 and the capacitor C11; the control terminal of the MOS transistor Q3 is electrically connected to the first switching terminal of the MOS transistor Q4; a second switching terminal of the MOS transistor Q3 is electrically connected to an anode of the thyristor SCR; both a control terminal of the MOS transistor Q4 and a control terminal of the thyristor SCR are connected to the leakage detection unit; the triode Q2, the triode Q1, the resistor R20 and the resistor R32 form a signal amplifier mechanism that is configured to amplify a circuit signal; the signal amplifier mechanism includes one terminal connected to the output terminal of the rectifier module unit, the other terminal connected between the diode D5 and the resistor R17, and a control terminal connected to an input terminal of the trip coil SOL; and a second switching terminal of the MOS transistor Q4, the second switching terminal of the MOS transistor Q3, a cathode of the thyristor SCR and an output terminal of the trip coil SOL are all grounded.

As a further solution to the present disclosure, the leakage detection unit includes a zero-sequence mutual inductance detector and a master control chip IC; and the zero-sequence mutual inductance detector is disposed around the power cord; and

the zero-sequence mutual inductance detector is connected to the master control chip IC; a power supply terminal of the master control chip IC is connected to the live wire input terminal, and configured to supply power to the master control chip IC; a first output terminal of the master control chip IC is electrically connected to the control terminal of the MOS transistor Q4; the control terminal of the thyristor SCR is electrically connected to a second output terminal of the master control chip IC; the zero-sequence mutual inductance detector is configured to sense leakage information and transmit the leakage information to the master control chip IC; and the master control chip IC is configured to control the triggering unit according to the leakage information.

As a further solution to the present disclosure, the leakage detection unit further includes an indicator lamp LED1; and the indicator lamp LED1 includes an anode electrically connected to a second output terminal of a master control chip IC, and a cathode grounded.

As a further solution to the present disclosure, the dual-detection leakage protector further includes a test switch S3; and the test switch S3 includes one terminal connected to the output terminal of the rectifier module unit, and the other terminal grounded, so as to realize a short-circuit test function.

As a further solution to the present disclosure, the dual-detection leakage protector further includes a leakage test switch S2; and the leakage test switch S2 is connected between the live wire input terminal and the live wire output terminal, so as to realize a leakage test function.

As a further solution to the present disclosure, the dual-detection leakage protector further includes a start indicator lamp; and the start indicator lamp is connected between the input terminal and the output terminal.

The present disclosure achieves the following beneficial effects: The dual-detection leakage protector has the temperature control detection function and the leakage detection function. Through the temperature control detection function of the temperature control detection unit, the dual-detection leakage protector can automatically cut off the circuit (namely disconnect the switching unit) in case of the over-current and over-temperature between the plug and the socket caused by poor contact, a short circuit and other conditions in the circuit. The leakage detection unit has the leakage detection function and the circuit element detection self-checking function. With the leakage detection function, the leakage detection unit can detect a leakage current on the power cord in real time, and can quickly cut off the circuit (namely disconnect the switching unit) once the leakage current exceeds a safety threshold. With the circuit element detection self-checking function, the leakage detection unit can timely check the circuit element for detection. The dual-detection leakage protector effectively prevents electrical fires, electric shock accidents and other potential safety hazards, greatly improving safety of the electrical environment.

### BRIEF DESCRIPTION OF THE DRAWINGS

FIG. 1 is a circuit diagram according to Embodiment 1 of the present disclosure;

FIG. 2 is a circuit diagram according to Embodiment 2 of the present disclosure;

FIG. 3 is a circuit diagram according to Embodiment 3 of the present disclosure; and

FIG. 4 is a schematic diagram according to the present disclosure.

### DETAILED DESCRIPTION OF THE EMBODIMENTS

To facilitate understanding of those skilled in the art on the present disclosure, specific implementations of the present disclosure are described below with reference to accompanying drawings.

It is to be noted that in the description of the present disclosure, terms such as “central”, “upper”, “lower”, “left”, “right” “vertical”, “horizontal”, “inside”, and “outside” indicate the orientation or position relationships based on the drawings. They are merely intended to facilitate and simplify the description of the present disclosure, rather than to indicate or imply that the mentioned device or components must have a specific orientation or must be constructed and operated in a specific orientation. Therefore, these terms should not be construed as a limitation to the present disclosure. Moreover, the terms “first”, “second”, and “third” are used only for the purpose of description, and are not intended to indicate or imply relative importance.

In the description of the present disclosure, it should be noted that, unless otherwise clearly specified, meanings of terms “install”, “connected with”, and “connected to” should be understood in a board sense. For example, the connection may be a fixed connection, a removable connection, or an integral connection; may be a mechanical connection or an electrical connection; may be a direct connection or an indirect connection by using an intermediate medium; or may be intercommunication between two components. Those of ordinary skill in the art may understand the specific meanings of the above terms in the present disclosure based on specific situations.

### Embodiment 1

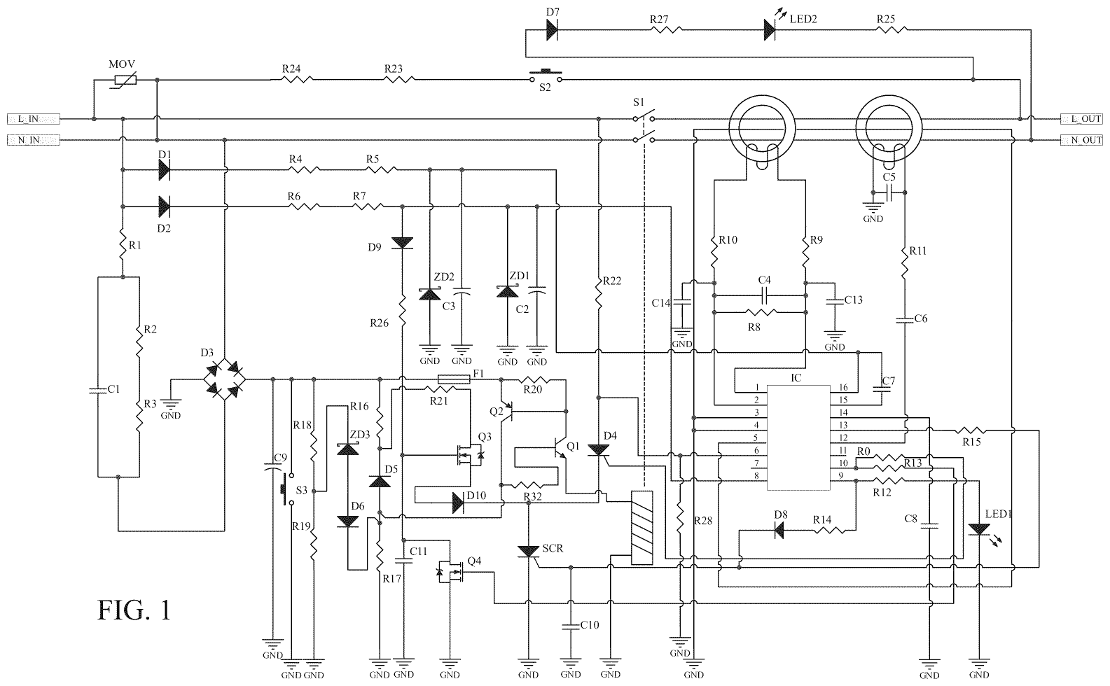

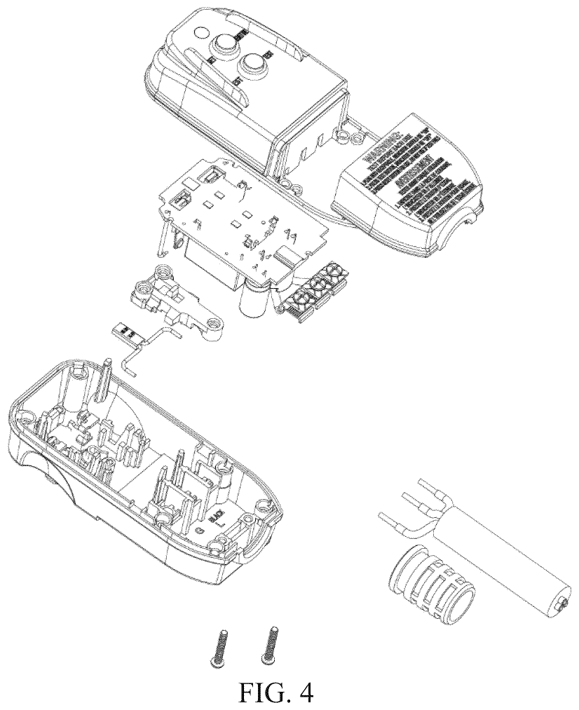

FIG. 1 and FIG. 4 show a technical solution in Embodiment 1 of the present disclosure. A dual-detection leakage protector includes a switching unit, a rectifier module unit, a temperature control detection unit, a leakage detection unit, and a triggering unit.

The switching unit is disposed between an input terminal and an output terminal, and configured to switch the input terminal and the output terminal on or off. The input terminal includes a live wire input terminal and a neutral wire input terminal. The output terminal includes a neutral wire output terminal electrically connected to the neutral wire input terminal and a live wire output terminal electrically connected to the live wire input terminal.

The rectifier module unit is connected between the input terminal and the output terminal, and configured to provide DC power for a circuit.

The temperature control detection unit includes one terminal connected to an output terminal of the rectifier module unit, and the other terminal connected to the triggering unit, and is configured to detect a temperature of a power cord plug-in connector.

The leakage detection unit is disposed around a power cord connected between the switching unit and the input terminal, and configured to detect whether the power cord has a leakage current.

The triggering unit is configured to acquire information of the temperature control detection unit or the leakage detection unit and control on-off of the switching unit, thereby cutting off the circuit.

As shown in FIG. 1, the temperature control detection unit is temperature control component F1. The temperature control component includes one terminal connected to the output terminal of the rectifier module unit, and the other terminal connected to the triggering unit. The temperature control component is disposed between the output terminal of the rectifier module unit and the triggering unit.

During use, in case of an over-current and an over-temperature between a plug and a socket caused by poor contact, a short circuit and other conditions in the circuit, the temperature control component is disconnected to cut off the circuit, thereby forming an open circuit. Consequently, a voltage difference is generated by a signal amplifier mechanism, and a current flows through trip coil SOL, thereby driving the trip coil SOL to control on-off of the switching unit, and cutting off the circuit.

As shown in FIG. 1, the triggering unit includes triode Q2, triode Q1, resistor R32, resistor R20, trip coil SOL, MOS transistor Q3, MOS transistor Q4, resistor R18, resistor R19, voltage stabilizing resistor ZD3, diode D6, resistor R16, diode D5, resistor R17, resistor R21, diode D10, diode D9, resistor R26, capacitor C11, and thyristor SCR. A terminal of the resistor R18 connected in series with the resistor R19 is connected to the output terminal of the rectifier module unit, and the other terminal of the resistor R18 is grounded. A terminal of the resistor R16 connected in series with the reversely disposed diode D5 and the resistor R17 is connected to the output terminal of the rectifier module unit, and the other terminal of the resistor R16 is grounded. The voltage stabilizing resistor ZD3 is connected in series with the diode D6, and includes one terminal connected between the resistor R18 and the resistor R19, and the other terminal connected between the reversely disposed diode D5 and the resistor R17. A first switching terminal of the MOS transistor Q3 is connected between the resistor R16 and the reversely disposed diode D5 through the resistor R21. The diode D9 is connected in series with the resistor R26 and the capacitor C11, and includes one terminal connected to the live wire input terminal, and the other terminal grounded. Both a control terminal of the MOS transistor Q3 and a first switching terminal of the MOS transistor Q4 are connected between the resistor R26 and the capacitor C11. The control terminal of the MOS transistor Q3 is electrically connected to the first switching terminal of the MOS transistor Q4. A second switching terminal of the MOS transistor Q3 is electrically connected to an anode of the thyristor SCR. Both a control terminal of the MOS transistor Q4 and a control terminal of the thyristor SCR are connected to the leakage detection unit. The triode Q2, the triode Q1, the resistor R20 and the resistor R32 form the signal amplifier mechanism that is configured to amplify a circuit signal. The signal amplifier mechanism includes one terminal connected to the output terminal of the rectifier module unit, the other terminal connected between the diode D5 and the resistor R17, and a control terminal connected to an input terminal of the trip coil SOL. A second switching terminal of the MOS transistor Q4, the second switching terminal of the MOS transistor Q3, a cathode of the thyristor SCR and an output terminal of the trip coil SOL are all grounded.

The leakage detection unit includes a zero-sequence mutual inductance detector and master control chip IC. The zero-sequence mutual inductance detector is disposed around the power cord.

The zero-sequence mutual inductance detector is connected to the master control chip IC. A power supply terminal of the master control chip IC is connected to the live wire input terminal, and configured to supply power to the master control chip IC. A first output terminal of the master control chip IC is electrically connected to the control terminal of the MOS transistor Q4. The control terminal of the thyristor SCR is electrically connected to a second output terminal of the master control chip IC. The zero-sequence mutual inductance detector is configured to sense leakage information and transmit the leakage information to the master control chip IC. The master control chip IC is configured to control the triggering unit according to the leakage information.

During use, in case of leakage on a loop, the zero-sequence mutual inductance detector detects the leakage. The second output terminal of the master control chip IC controls the thyristor SCR to be conducted, causing disconnection of the MOS transistor Q3. The voltage of the circuit drops, the signal amplifier mechanism generates a voltage difference, and a current flows through the trip coil SOL, thereby driving the trip coil SOL to control on-off of the switching unit, and cutting off the circuit.

Automatic detection is performed on the circuit regularly. The detection process is as follows: The first output terminal of the master control chip IC1 controls the MOS transistor Q4 to be conducted, causing disconnection of the MOS transistor Q3.

When the MOS transistor Q4 and the MOS transistor Q3 operate normally, the input terminal of the master control chip IC is switched between a high level and a low level.

When the MOS transistor Q4 and the MOS transistor Q3 are damaged, the MOS transistor Q3 remains in a conducted state, the input terminal of the master control chip IC is suspended all the time, and the voltage is unchanged.

With regular checking on a loop element in the circuit, an abnormal condition of the element can be discovered in advance, ensuring safety of the electrical appliance and the user.

As shown in FIG. 1, the leakage detection unit further includes indicator lamp LED1. The indicator lamp LED1 includes an anode electrically connected to the second output terminal of the master control chip IC, and a cathode grounded. When the element is abnormal, the indicator lamp LED1 is turned on to alert the user.

As shown in FIG. 1, the dual-detection leakage protector further includes test switch S3. The test switch S3 includes one terminal connected to the output terminal of the rectifier module unit, and the other terminal grounded, so as to realize a short-circuit test function.

As shown in FIG. 1, the dual-detection leakage protector further includes leakage test switch S2. The leakage test switch S2 is connected between the live wire input terminal and the live wire output terminal, so as to realize a leakage test function.

As shown in FIG. 1, the dual-detection leakage protector further includes a start indicator lamp. The start indicator lamp is connected between the input terminal and the output terminal. When the dual-detection leakage protector is disconnected, the start indicator lamp LED2 is turned off to give an alarm visually, alerting the user of a state of the dual-detection leakage protector.

### Embodiment 2

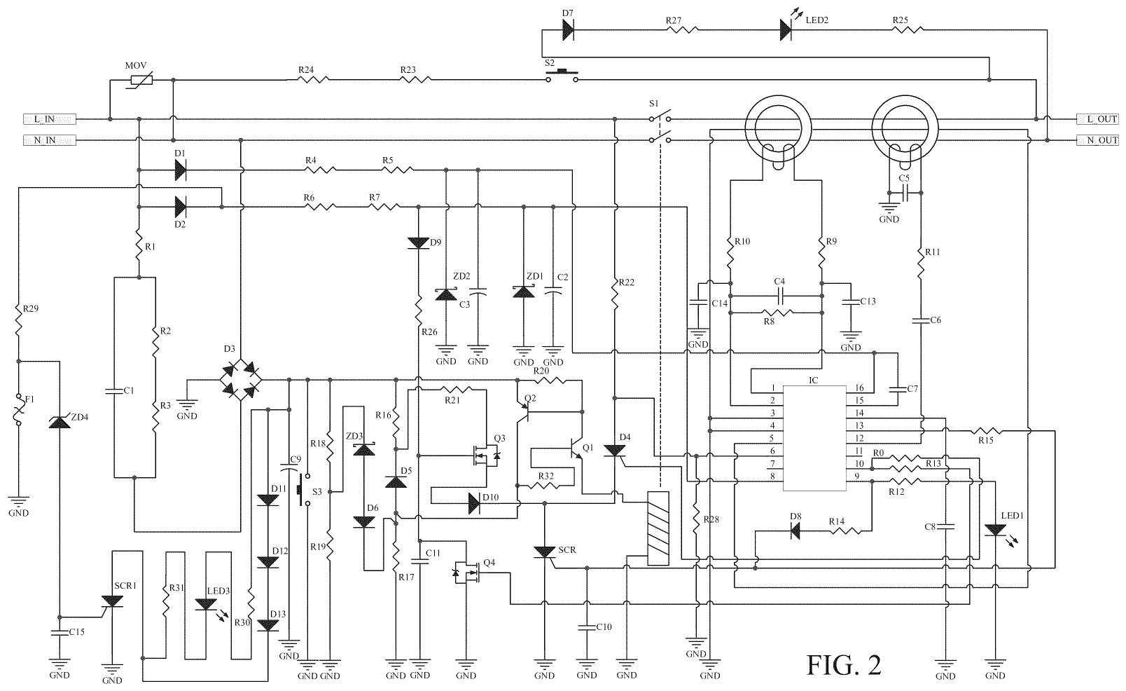

FIG. 2 and FIG. 4 show a technical solution in Embodiment 2 of the present disclosure. A dual-detection leakage protector includes a switching unit, a rectifier module unit, a temperature control detection unit, a leakage detection unit, and a triggering unit.

The switching unit is disposed between an input terminal and an output terminal, and configured to switch the input terminal and the output terminal on or off. The input terminal includes a live wire input terminal and a neutral wire input terminal. The output terminal includes a neutral wire output terminal electrically connected to the neutral wire input terminal and a live wire output terminal electrically connected to the live wire input terminal.

The rectifier module unit is connected between the input terminal and the output terminal, and configured to provide DC power for a circuit.

The temperature control detection unit includes one terminal connected to an output terminal of the rectifier module unit, and the other terminal connected to the triggering unit, and is configured to detect a temperature of a power cord plug-in connector.

The leakage detection unit is disposed around a power cord connected between the switching unit and the input terminal, and configured to detect whether the power cord has a leakage current.

The triggering unit is configured to acquire information of the temperature control detection unit or the leakage detection unit and control on-off of the switching unit, thereby cutting off the circuit.

As shown in FIG. 2, the temperature control detection unit includes temperature control switch F1, resistor R29, thyristor SCR1, diode D11, diode D12, and diode D13. The temperature control switch includes one terminal grounded, and the other terminal connected to the live wire input terminal through the resistor R29. The thyristor SCR1 includes a control terminal connected between the temperature control switch and the resistor R29, a cathode grounded, and an anode connecting the diode D11, the diode D12 and the diode D13 in series to the triggering unit.

During use, in case of an over-current and an over-temperature between a plug and a socket caused by poor contact, a short circuit and other conditions in the circuit, the temperature control switch is disconnected, and the thyristor SCR1 is conducted, thereby forming an open circuit. Consequently, a voltage difference is generated by a signal amplifier mechanism, and a current flows through trip coil SOL, thereby driving the trip coil SOL to control on-off of the switching unit, and cutting off the circuit. With the temperature control switch, the dual-detection leakage protector can be restarted without changing a temperature control component.

As shown in FIG. 2, the temperature control detection unit is provided with warning lamp LED3. When the thyristor SCR1 is conducted, the warning lamp LED3 is turned on to give an alarm visually, alerting the user of a state of the dual-detection leakage protector.

As shown in FIG. 2, the triggering unit includes triode Q2, triode Q1, resistor R32, resistor R20, trip coil SOL, MOS transistor Q3, MOS transistor Q4, resistor R18, resistor R19, voltage stabilizing resistor ZD3, diode D6, resistor R16, diode D5, resistor R17, resistor R21, diode D10, diode D9, resistor R26, capacitor C11, and thyristor SCR. A terminal of the resistor R18 connected in series with the resistor R19 is connected to the output terminal of the rectifier module unit, and the other terminal of the resistor R18 is grounded. A terminal of the resistor R16 connected in series with the reversely disposed diode D5 and the resistor R17 is connected to the output terminal of the rectifier module unit, and the other terminal of the resistor R16 is grounded. The voltage stabilizing resistor ZD3 is connected in series with the diode D6, and includes one terminal connected between the resistor R18 and the resistor R19, and the other terminal connected between the reversely disposed diode D5 and the resistor R17. A first switching terminal of the MOS transistor Q3 is connected between the resistor R16 and the reversely disposed diode D5 through the resistor R21. The diode D9 is connected in series with the resistor R26 and the capacitor C11, and includes one terminal connected to the live wire input terminal, and the other terminal grounded. Both a control terminal of the MOS transistor Q3 and a first switching terminal of the MOS transistor Q4 are connected between the resistor R26 and the capacitor C11. The control terminal of the MOS transistor Q3 is electrically connected to the first switching terminal of the MOS transistor Q4. A second switching terminal of the MOS transistor Q3 is electrically connected to an anode of the thyristor SCR. Both a control terminal of the MOS transistor Q4 and a control terminal of the thyristor SCR are connected to the leakage detection unit. The triode Q2, the triode Q1, the resistor R20 and the resistor R32 form the signal amplifier mechanism that is configured to amplify a circuit signal. The signal amplifier mechanism includes one terminal connected to the output terminal of the rectifier module unit, the other terminal connected between the diode D5 and the resistor R17, and a control terminal connected to an input terminal of the trip coil SOL. A second switching terminal of the MOS transistor Q4, the second switching terminal of the MOS transistor Q3, a cathode of the thyristor SCR and an output terminal of the trip coil SOL are all grounded.

The leakage detection unit includes a zero-sequence mutual inductance detector and master control chip IC. The zero-sequence mutual inductance detector is disposed around the power cord.

The zero-sequence mutual inductance detector is connected to the master control chip IC. A power supply terminal of the master control chip IC is connected to the live wire input terminal, and configured to supply power to the master control chip IC. A first output terminal of the master control chip IC is electrically connected to the control terminal of the MOS transistor Q4. The control terminal of the thyristor SCR is electrically connected to a second output terminal of the master control chip IC. The zero-sequence mutual inductance detector is configured to sense leakage information and transmit the leakage information to the master control chip IC. The master control chip IC is configured to control the triggering unit according to the leakage information.

During use, in case of leakage on a loop, the zero-sequence mutual inductance detector detects the leakage. The second output terminal of the master control chip IC controls the thyristor SCR to be conducted, causing disconnection of the MOS transistor Q3. The voltage of the circuit drops, the signal amplifier mechanism generates a voltage difference, and a current flows through the trip coil SOL, thereby driving the trip coil SOL to control on-off of the switching unit, and cutting off the circuit.

Automatic detection is performed on the circuit regularly. The detection process is as follows: The first output terminal of the master control chip IC1 controls the MOS transistor Q4 to be conducted, causing disconnection of the MOS transistor Q3.

When the MOS transistor Q4 and the MOS transistor Q3 operate normally, the input terminal of the master control chip IC is switched between a high level and a low level.

When the MOS transistor Q4 and the MOS transistor Q3 are damaged, the MOS transistor Q3 remains in a conducted state, the input terminal of the master control chip IC is suspended all the time, and the voltage is unchanged.

With regular checking on a loop element in the circuit, an abnormal condition of the element can be discovered in advance, ensuring safety of the electrical appliance and the user.

As shown in FIG. 2, the leakage detection unit further includes indicator lamp LED1. The indicator lamp LED1 includes an anode electrically connected to the second output terminal of the master control chip IC, and a cathode grounded. When the element is abnormal, the indicator lamp LED1 is turned on to alert the user.

As shown in FIG. 2, the dual-detection leakage protector further includes test switch S3. The test switch S3 includes one terminal connected to the output terminal of the rectifier module unit, and the other terminal grounded, so as to realize a short-circuit test function.

As shown in FIG. 2, the dual-detection leakage protector further includes leakage test switch S2. The leakage test switch S2 is connected between the live wire input terminal and the live wire output terminal, so as to realize a leakage test function.

As shown in FIG. 2, the dual-detection leakage protector further includes a start indicator lamp. The start indicator lamp is connected between the input terminal and the output terminal. When the dual-detection leakage protector is disconnected, the start indicator lamp LED2 is turned off to give an alarm visually, alerting the user of a state of the dual-detection leakage protector.

### Embodiment 3

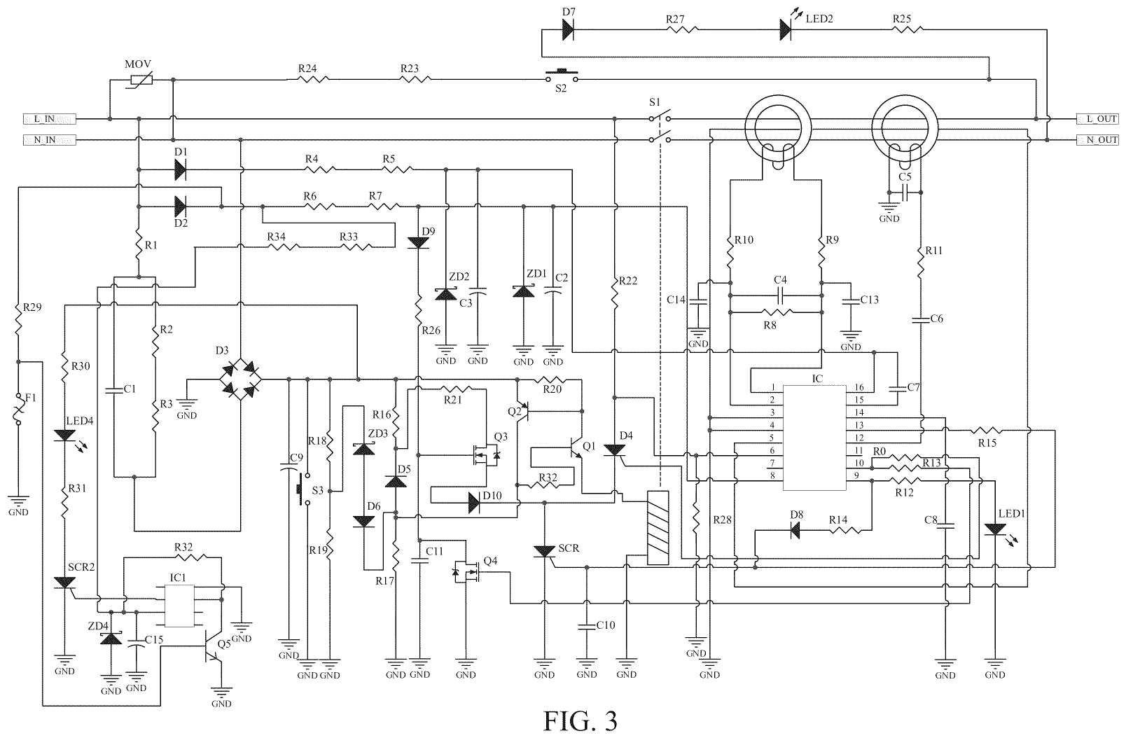

FIG. 3 and FIG. 4 show a technical solution in Embodiment 3 of the present disclosure. A dual-detection leakage protector includes a switching unit, a rectifier module unit, a temperature control detection unit, a leakage detection unit, and a triggering unit.

The switching unit is disposed between an input terminal and an output terminal, and configured to switch the input terminal and the output terminal on or off. The input terminal includes a live wire input terminal and a neutral wire input terminal. The output terminal includes a neutral wire output terminal electrically connected to the neutral wire input terminal and a live wire output terminal electrically connected to the live wire input terminal.

The rectifier module unit is connected between the input terminal and the output terminal, and configured to provide DC power for a circuit.

The temperature control detection unit includes one terminal connected to an output terminal of the rectifier module unit, and the other terminal connected to the triggering unit, and is configured to detect a temperature of a power cord plug-in connector.

The leakage detection unit is disposed around a power cord connected between the switching unit and the input terminal, and configured to detect whether the power cord has a leakage current.

The triggering unit is configured to acquire information of the temperature control detection unit or the leakage detection unit and control on-off of the switching unit, thereby cutting off the circuit.

As shown in FIG. 3, the temperature control detection unit includes temperature control switch F1, resistor R29, control chip IC1, triode Q5, thyristor SCR2, resistor R30, and warning lamp LED4. The temperature control switch includes one terminal grounded, and the other terminal connected to the live wire input terminal through the resistor R29. A base of the triode Q5 is connected between the temperature control switch and the resistor R29, and connected to an input terminal of the control chip IC1. The thyristor SCR2 includes a control terminal connected to an output terminal of the control chip IC1, a cathode grounded, and an anode connecting the warning lamp LED4 and the resistor R30 in series to the output terminal of the rectifier module unit.

During use, in case of an over-current and an over-temperature between a plug and a socket caused by poor contact, a short circuit and other conditions in the circuit, the temperature control switch is disconnected, the control chip IC1 is triggered, and the thyristor SCR2 is conducted, thereby forming an open circuit. Consequently, a voltage difference is generated by a signal amplifier mechanism, and a current flows through trip coil SOL, thereby driving the trip coil SOL to control on-off of the switching unit, and cutting off the circuit.

Meanwhile, when the thyristor SCR2 is conducted, the warning lamp LED3 is turned on to give an alarm visually, alerting the user of a state of the dual-detection leakage protector.

As shown in FIG. 3, the triggering unit includes triode Q2, triode Q1, resistor R32, resistor R20, trip coil SOL, MOS transistor Q3, MOS transistor Q4, resistor R18, resistor R19, voltage stabilizing resistor ZD3, diode D6, resistor R16, diode D5, resistor R17, resistor R21, diode D10, diode D9, resistor R26, capacitor C11, and thyristor SCR. A terminal of the resistor R18 connected in series with the resistor R19 is connected to the output terminal of the rectifier module unit, and the other terminal of the resistor R18 is grounded. A terminal of the resistor R16 connected in series with the reversely disposed diode D5 and the resistor R17 is connected to the output terminal of the rectifier module unit, and the other terminal of the resistor R16 is grounded. The voltage stabilizing resistor ZD3 is connected in series with the diode D6, and includes one terminal connected between the resistor R18 and the resistor R19, and the other terminal connected between the reversely diode D5 and the resistor R17. A first switching terminal of the MOS transistor Q3 is connected between the resistor R16 and the reversely disposed diode D5 through the resistor R21. The diode D9 is connected in series with the resistor R26 and the capacitor C11, and includes one terminal connected to the live wire input terminal, and the other terminal grounded. Both a control terminal of the MOS transistor Q3 and a first switching terminal of the MOS transistor Q4 are connected between the resistor R26 and the capacitor C11. The control terminal of the MOS transistor Q3 is electrically connected to the first switching terminal of the MOS transistor Q4. A second switching terminal of the MOS transistor Q3 is electrically connected to an anode of the thyristor SCR. Both a control terminal of the MOS transistor Q4 and a control terminal of the thyristor SCR are connected to the leakage detection unit. The triode Q2, the triode Q1, the resistor R20 and the resistor R32 form the signal amplifier mechanism that is configured to amplify a circuit signal. The signal amplifier mechanism includes one terminal connected to the output terminal of the rectifier module unit, the other terminal connected between the diode D5 and the resistor R17, and a control terminal connected to an input terminal of the trip coil SOL. A second switching terminal of the MOS transistor Q4, the second switching terminal of the MOS transistor Q3, a cathode of the thyristor SCR and an output terminal of the trip coil SOL are all grounded.

The leakage detection unit includes a zero-sequence mutual inductance detector and master control chip IC. The zero-sequence mutual inductance detector is disposed around the power cord.

The zero-sequence mutual inductance detector is connected to the master control chip IC. A power supply terminal of the master control chip IC is connected to the live wire input terminal, and configured to supply power to the master control chip IC. A first output terminal of the master control chip IC is electrically connected to the control terminal of the MOS transistor Q4. The control terminal of the thyristor SCR is electrically connected to a second output terminal of the master control chip IC. The zero-sequence mutual inductance detector is configured to sense leakage information and transmit the leakage information to the master control chip IC. The master control chip IC is configured to control the triggering unit according to the leakage information.

During use, in case of leakage on a loop, the zero-sequence mutual inductance detector detects the leakage. The second output terminal of the master control chip IC controls the thyristor SCR to be conducted, causing disconnection of the MOS transistor Q3. The voltage of the circuit drops, the signal amplifier mechanism generates a voltage difference, and a current flows through the trip coil SOL, thereby driving the trip coil SOL to control on-off of the switching unit, and cutting off the circuit.

Automatic detection is performed on the circuit regularly. The detection process is as follows: The first output terminal of the master control chip IC1 controls the MOS transistor Q4 to be conducted, causing disconnection of the MOS transistor Q3.

When the MOS transistor Q4 and the MOS transistor Q3 operate normally, the input terminal of the master control chip IC is switched between a high level and a low level.

When the MOS transistor Q4 and the MOS transistor Q3 are damaged, the MOS transistor Q3 remains in a conducted state, the input terminal of the master control chip IC is suspended all the time, and the voltage is unchanged.

With regular checking on a loop element in the circuit, an abnormal condition of the element can be discovered in advance, ensuring safety of the electrical appliance and the user.

As shown in FIG. 3, the leakage detection unit further includes indicator lamp LED1. The indicator lamp LED1 includes an anode electrically connected to the second output terminal of the master control chip IC, and a cathode grounded. When the element is abnormal, the indicator lamp LED1 is turned on to alert the user.

As shown in FIG. 3, the dual-detection leakage protector further includes test switch S3. The test switch S3 includes one terminal connected to the output terminal of the rectifier module unit, and the other terminal grounded, so as to realize a short-circuit test function.

As shown in FIG. 3, the dual-detection leakage protector further includes leakage test switch S2. The leakage test switch S2 is connected between the live wire input terminal and the live wire output terminal, so as to realize a leakage test function.

As shown in FIG. 3, the dual-detection leakage protector further includes a start indicator lamp. The start indicator lamp is connected between the input terminal and the output terminal. When the dual-detection leakage protector is disconnected, the start indicator lamp LED2 is turned off to give an alarm visually, alerting the user of a state of the dual-detection leakage protector.

The implementations described above do not constitute a limitation on the protection scope of the present disclosure. Any modifications, equivalent substitutions, improvements, etc. made within the spirit and principle of the present disclosure should be included in the protection scope of the claims of the present disclosure.

What is claimed is:

1. A dual-detection leakage protector, comprising: a switching unit, a rectifier module unit,
a temperature control detection unit, a leakage detection unit, and a triggering unit, wherein the switching unit is disposed between an input terminal and an output terminal, and configured to switch the input terminal and the output terminal on or off; the input terminal comprises a live wire input terminal and a neutral wire input terminal; the output terminal comprises a neutral wire output terminal electrically connected to the neutral wire input terminal and a live wire output terminal electrically connected to the live wire input terminal;
the rectifier module unit is connected between the input terminal and the output terminal, and configured to provide direct current (DC) power for a circuit; the temperature control detection unit comprises a first terminal connected to an output terminal of the rectifier module unit, and a second terminal connected to the triggering unit, and is configured to detect a temperature of a power cord plug-in connector;
the leakage detection unit is disposed around a power cord connected between the switching unit and the input terminal, and configured to detect whether the power cord has a leakage current; and the triggering unit is configured to acquire information of the temperature control detection unit or the leakage detection unit and control on-off of the switching unit, comprising cutting off the circuit.

2. The dual-detection leakage protector according to claim 1, wherein the temperature control detection unit is a temperature control component; and the temperature control component comprises a first terminal connected to the output terminal of the rectifier module unit, and a second terminal connected to the triggering unit.

3. The dual-detection leakage protector according to claim 1, wherein the temperature control detection unit comprises a temperature control switch, a resistor R29, a thyristor SCR1, a diode D11, a diode D12, and a diode D13; the temperature control switch comprises a first terminal grounded, and a second terminal connected to the live wire input terminal through the resistor R29; and the thyristor SCR1 comprises a control terminal connected between the temperature control switch and the resistor R29, a cathode grounded, and an anode connecting the diode D11, the diode D12 and the diode D13 in series to the triggering unit.

4. The dual-detection leakage protector according to claim 1, wherein the temperature control detection unit comprises a temperature control switch, a resistor R29, a control chip IC1, a triode Q5, a thyristor SCR2, a resistor R30, and a warning lamp LED4;
the temperature control switch comprises a first terminal grounded, and a second terminal connected to the live wire input terminal through the resistor R29; a base of the triode Q5 is connected between the temperature control switch and the resistor R29, and connected to an input terminal of the control chip IC1; and the thyristor SCR2 comprises a control terminal connected to an output terminal of the control chip IC1, a cathode grounded, and an anode connecting the warning lamp LED4 and the resistor R30 in series to the output terminal of the rectifier module unit.

5. The dual-detection leakage protector according to claim 1, wherein the triggering unit comprises a triode Q2, a triode Q1, a resistor R32, a resistor R20, a trip coil SOL, a metal oxide semiconductor (MOS) transistor Q3, an MOS transistor Q4, a resistor R18, a resistor R19, a voltage stabilizing resistor ZD3, a diode D6, a resistor R16, a diode D5, a resistor R17, a resistor R21, a diode D10, a diode D9, a resistor R26, a capacitor C11, and a thyristor SCR;
a first terminal of the resistor R18 connected in series with the resistor R19 is connected to the output terminal of the rectifier module unit, and a second terminal of the resistor R18 is grounded; a first terminal of the resistor R16 connected in series with a reversely disposed diode D5 and the resistor R17 is connected to the output terminal of the rectifier module unit, and a second terminal of the resistor R16 is grounded; the voltage stabilizing resistor ZD3 is connected in series with the diode D6, and comprises a first terminal connected between the resistor R18 and the resistor R19, and a second terminal connected between the reversely disposed diode D5 and the resistor R17;
a first switching terminal of the MOS transistor Q3 is connected between the resistor R16 and the reversely disposed diode D5 through the resistor R21; the diode D9 is connected in series with the resistor R26 and the capacitor C11, and comprises a first terminal connected to the live wire input terminal, and a second terminal grounded; both a control terminal of the MOS transistor Q3 and a first switching terminal of the MOS transistor Q4 are connected between the resistor R26 and the capacitor C11; the control terminal of the MOS transistor Q3 is electrically connected to the first switching terminal of the MOS transistor Q4; a second switching terminal of the MOS transistor Q3 is electrically connected to an anode of the thyristor SCR;
both a control terminal of the MOS transistor Q4 and a control terminal of the thyristor SCR are connected to the leakage detection unit; the triode Q2, the triode Q1, the resistor R20 and the resistor R32 form a signal amplifier mechanism that is configured to amplify a circuit signal; the signal amplifier mechanism comprises a first terminal connected to the output terminal of the rectifier module unit, a second terminal connected between the diode D5 and the resistor R17, and a control terminal connected to an input terminal of the trip coil SOL; and a second switching terminal of the MOS transistor Q4, the second switching terminal of the MOS transistor Q3, a cathode of the thyristor SCR and an output terminal of the trip coil SOL are all grounded.

6. The dual-detection leakage protector according to claim 5, wherein the leakage detection unit comprises a zero-sequence mutual inductance detector and a master control chip IC; and the zero-sequence mutual inductance detector is disposed around the power cord; and
the zero-sequence mutual inductance detector is connected to the master control chip IC; a power supply terminal of the master control chip IC is connected to the live wire input terminal, and configured to supply power to the master control chip IC; a first output terminal of the master control chip IC is electrically connected to the control terminal of the MOS transistor Q4; the control terminal of the thyristor SCR is electrically connected to a second output terminal of the master control chip IC; the zero-sequence mutual inductance detector is configured to sense leakage information and transmit the leakage information to the master control chip IC; and the master control chip IC is configured to control the triggering unit according to the leakage information.

7. The dual-detection leakage protector according to claim 6, wherein the leakage detection unit further comprises an indicator lamp LED1; and the indicator lamp LED1 comprises an anode electrically connected to the second output terminal of the master control chip IC, and a cathode grounded.

8. The dual-detection leakage protector according to claim 5, further comprising a test switch S3, wherein the test switch S3 comprises a first terminal connected to the output terminal of the rectifier module unit, and a second terminal grounded, wherein a short-circuit test function is realized.

9. The dual-detection leakage protector according to claim 8, further comprising a leakage test switch S2, wherein the leakage test switch S2 is connected between the live wire input terminal and the live wire output terminal, wherein a leakage test function is realized.

10. The dual-detection leakage protector according to claim 9, further comprising a start indicator lamp, wherein the start indicator lamp is connected between the input terminal and the output terminal.

11. The dual-detection leakage protector according to claim 2, wherein the triggering unit comprises a triode Q2, a triode Q1, a resistor R32, a resistor R20, a trip coil SOL, a metal oxide semiconductor (MOS) transistor Q3, an MOS transistor Q4, a resistor R18, a resistor R19, a voltage stabilizing resistor ZD3, a diode D6, a resistor R16, a diode D5, a resistor R17, a resistor R21, a diode D10, a diode D9, a resistor R26, a capacitor C11, and a thyristor SCR;
a first terminal of the resistor R18 connected in series with the resistor R19 is connected to the output terminal of the rectifier module unit, and a second terminal of the resistor R18 is grounded; a first terminal of the resistor R16 connected in series with a reversely disposed diode D5 and the resistor R17 is connected to the output terminal of the rectifier module unit, and a second terminal of the resistor R16 is grounded; the voltage stabilizing resistor ZD3 is connected in series with the diode D6, and comprises a first terminal connected between the resistor R18 and the resistor R19, and a second terminal connected between the reversely disposed diode D5 and the resistor R17;
a first switching terminal of the MOS transistor Q3 is connected between the resistor R16 and the reversely disposed diode D5 through the resistor R21; the diode D9 is connected in series with the resistor R26 and the capacitor C11, and comprises a first terminal connected to the live wire input terminal, and a second terminal grounded; both a control terminal of the MOS transistor Q3 and a first switching terminal of the MOS transistor Q4 are connected between the resistor R26 and the capacitor C11; the control terminal of the MOS transistor Q3 is electrically connected to the first switching terminal of the MOS transistor Q4; a second switching terminal of the MOS transistor Q3 is electrically connected to an anode of the thyristor SCR;
both a control terminal of the MOS transistor Q4 and a control terminal of the thyristor SCR are connected to the leakage detection unit; the triode Q2, the triode Q1, the resistor R20 and the resistor R32 form a signal amplifier mechanism that is configured to amplify a circuit signal; the signal amplifier mechanism comprises a first terminal connected to the output terminal of the rectifier module unit, a second terminal connected between the diode D5 and the resistor R17, and a control terminal connected to an input terminal of the trip coil SOL; and a second switching terminal of the MOS transistor Q4, the second switching terminal of the MOS transistor Q3, a cathode of the thyristor SCR and an output terminal of the trip coil SOL are all grounded.

12. The dual-detection leakage protector according to claim 3, wherein the triggering unit comprises a triode Q2, a triode Q1, a resistor R32, a resistor R20, a trip coil SOL, a metal oxide semiconductor (MOS) transistor Q3, an MOS transistor Q4, a resistor R18, a resistor R19, a voltage stabilizing resistor ZD3, a diode D6, a resistor R16, a diode D5, a resistor R17, a resistor R21, a diode D10, a diode D9, a resistor R26, a capacitor C11, and a thyristor SCR;
a first terminal of the resistor R18 connected in series with the resistor R19 is connected to the output terminal of the rectifier module unit, and a second terminal of the resistor R18 is grounded; a first terminal of the resistor R16 connected in series with a reversely disposed diode D5 and the resistor R17 is connected to the output terminal of the rectifier module unit, and a second terminal of the resistor R16 is grounded; the voltage stabilizing resistor ZD3 is connected in series with the diode D6, and comprises a first terminal connected between the resistor R18 and the resistor R19, and a second terminal connected between the reversely disposed diode D5 and the resistor R17;
a first switching terminal of the MOS transistor Q3 is connected between the resistor R16 and the reversely disposed diode D5 through the resistor R21; the diode D9 is connected in series with the resistor R26 and the capacitor C11, and comprises a first terminal connected to the live wire input terminal, and a second terminal grounded; both a control terminal of the MOS transistor Q3 and a first switching terminal of the MOS transistor Q4 are connected between the resistor R26 and the capacitor C11; the control terminal of the MOS transistor Q3 is electrically connected to the first switching terminal of the MOS transistor Q4; a second switching terminal of the MOS transistor Q3 is electrically connected to an anode of the thyristor SCR;
both a control terminal of the MOS transistor Q4 and a control terminal of the thyristor SCR are connected to the leakage detection unit; the triode Q2, the triode Q1, the resistor R20 and the resistor R32 form a signal amplifier mechanism that is configured to amplify a circuit signal; the signal amplifier mechanism comprises a first terminal connected to the output terminal of the rectifier module unit, a second terminal connected between the diode D5 and the resistor R17, and a control terminal connected to an input terminal of the trip coil SOL; and a second switching terminal of the MOS transistor Q4, the second switching terminal of the MOS transistor Q3, a cathode of the thyristor SCR and an output terminal of the trip coil SOL are all grounded.

13. The dual-detection leakage protector according to claim 4, wherein the triggering unit comprises a triode Q2, a triode Q1, a resistor R32, a resistor R20, a trip coil SOL, a metal oxide semiconductor (MOS) transistor Q3, an MOS transistor Q4, a resistor R18, a resistor R19, a voltage stabilizing resistor ZD3, a diode D6, a resistor R16, a diode D5, a resistor R17, a resistor R21, a diode D10, a diode D9, a resistor R26, a capacitor C11, and a thyristor SCR;
a first terminal of the resistor R18 connected in series with the resistor R19 is connected to the output terminal of the rectifier module unit, and a second terminal of the resistor R18 is grounded; a first terminal of the resistor R16 connected in series with a reversely disposed diode D5 and the resistor R17 is connected to the output terminal of the rectifier module unit, and a second terminal of the resistor R16 is grounded; the voltage stabilizing resistor ZD3 is connected in series with the diode D6, and comprises a first terminal connected between the resistor R18 and the resistor R19, and a second terminal connected between the reversely disposed diode D5 and the resistor R17;
a first switching terminal of the MOS transistor Q3 is connected between the resistor R16 and the reversely disposed diode D5 through the resistor R21; the diode D9 is connected in series with the resistor R26 and the capacitor C11, and comprises a first terminal connected to the live wire input terminal, and a second terminal grounded; both a control terminal of the MOS transistor Q3 and a first switching terminal of the MOS transistor Q4 are connected between the resistor R26 and the capacitor C11; the control terminal of the MOS transistor Q3 is electrically connected to the first switching terminal of the MOS transistor Q4; a second switching terminal of the MOS transistor Q3 is electrically connected to an anode of the thyristor SCR;
both a control terminal of the MOS transistor Q4 and a control terminal of the thyristor SCR are connected to the leakage detection unit; the triode Q2, the triode Q1, the resistor R20 and the resistor R32 form a signal amplifier mechanism that is configured to amplify a circuit signal; the signal amplifier mechanism comprises a first terminal connected to the output terminal of the rectifier module unit, a second terminal connected between the diode D5 and the resistor R17, and a control terminal connected to an input terminal of the trip coil SOL; and a second switching terminal of the MOS transistor Q4, the second switching terminal of the MOS transistor Q3, a cathode of the thyristor SCR and an output terminal of the trip coil SOL are all grounded.

14. The dual-detection leakage protector according to claim 11, wherein the leakage detection unit comprises a zero-sequence mutual inductance detector and a master control chip IC; and the zero-sequence mutual inductance detector is disposed around the power cord; and
the zero-sequence mutual inductance detector is connected to the master control chip IC; a power supply terminal of the master control chip IC is connected to the live wire input terminal, and configured to supply power to the master control chip IC; a first output terminal of the master control chip IC is electrically connected to the control terminal of the MOS transistor Q4; the control terminal of the thyristor SCR is electrically connected to a second output terminal of the master control chip IC; the zero-sequence mutual inductance detector is configured to sense leakage information and transmit the leakage information to the master control chip IC; and the master control chip IC is configured to control the triggering unit according to the leakage information.

15. The dual-detection leakage protector according to claim 12, wherein the leakage detection unit comprises a zero-sequence mutual inductance detector and a master control chip IC; and the zero-sequence mutual inductance detector is disposed around the power cord; and
the zero-sequence mutual inductance detector is connected to the master control chip IC; a power supply terminal of the master control chip IC is connected to the live wire input terminal, and configured to supply power to the master control chip IC; a first output terminal of the master control chip IC is electrically connected to the control terminal of the MOS transistor Q4; the control terminal of the thyristor SCR is electrically connected to a second output terminal of the master control chip IC; the zero-sequence mutual inductance detector is configured to sense leakage information and transmit the leakage information to the master control chip IC; and the master control chip IC is configured to control the triggering unit according to the leakage information.

16. The dual-detection leakage protector according to claim 13, wherein the leakage detection unit comprises a zero-sequence mutual inductance detector and a master control chip IC; and the zero-sequence mutual inductance detector is disposed around the power cord; and
the zero-sequence mutual inductance detector is connected to the master control chip IC; a power supply terminal of the master control chip IC is connected to the live wire input terminal, and configured to supply power to the master control chip IC; a first output terminal of the master control chip IC is electrically connected to the control terminal of the MOS transistor Q4; the control terminal of the thyristor SCR is electrically connected to a second output terminal of the master control chip IC; the zero-sequence mutual inductance detector is configured to sense leakage information and transmit the leakage information to the master control chip IC; and the master control chip IC is configured to control the triggering unit according to the leakage information.

17. The dual-detection leakage protector according to claim 14, wherein the leakage detection unit further comprises an indicator lamp LED1; and the indicator lamp LED1 comprises an anode electrically connected to the second output terminal of the master control chip IC, and a cathode grounded.

18. The dual-detection leakage protector according to claim 15, wherein the leakage detection unit further comprises an indicator lamp LED1; and the indicator lamp LED1 comprises an anode electrically connected to the second output terminal of the master control chip IC, and a cathode grounded.

19. The dual-detection leakage protector according to claim 16, wherein the leakage detection unit further comprises an indicator lamp LED1; and the indicator lamp LED1 comprises an anode electrically connected to the second output terminal of the master control chip IC, and a cathode grounded.

20. The dual-detection leakage protector according to claim 11, further comprising a test switch S3, wherein the test switch S3 comprises a first terminal connected to the output terminal of the rectifier module unit, and a second terminal grounded, wherein a short-circuit test function is realized.
